(19) United States
(12) Patent Application Publication
(10) Pub. No.: US 2024/0222504 A1
(43) Pub. Date: Jul. 4, 2024

(54) TRANSISTOR WITH INTEGRATED SOURCE-DRAIN DIODE

(71) Applicant: Qorvo US, Inc., Greensboro, NC (US)

(72) Inventors: Anup Bhalla, Princeton, NJ (US); Leonid Fursin, Monmouth Junction, NJ (US)

(21) Appl. No.: 18/533,355

(22) Filed: Dec. 8, 2023

Related U.S. Application Data
(60) Provisional application No. 63/477,724, filed on Dec. 29, 2022.

(51) Int. Cl. H01L 29/78; H01L 29/10; H01L 29/16; H01L 29/423; H01L 29/66

(52) U.S. Cl. CPC H01L 29/7832; H01L 29/1045; H01L 29/1095; H01L 29/1608; H01L 29/4236; H01L 29/66893

(57) ABSTRACT

Vertical junction field-effect transistors (VJFETs) with integrated source-drain anti-parallel diodes are described. In an embodiment, a trench VJFET with integrated source-drain anti-parallel diodes structure is coupled with a low-voltage metal oxide semiconductor field-effect transistor (MOSFET) in a dual gate cascode configuration.

### RELATED APPLICATIONS

This application claims the benefit of provisional patent application Ser. No. 63/477,724, filed Dec. 29, 2022, the disclosure of which is hereby incorporated herein by reference in its entirety.

### FIELD OF THE DISCLOSURE

The present disclosure relates generally to semiconductor technology and in particular to depletion-mode trench gate vertical junction field-effect transistors with integrated source-drain anti-parallel diodes.

### BACKGROUND

Vertical junction field-effect transistors (VJFETs) built on silicon carbide (SiC) are of great interest for high-power conversion applications and power electronic circuits. Conventional trench VJFET structures are created by etching trenches into a topside of a semiconductor material wherein gate regions are formed on both sides and bottoms of the trenches such that mirror-image replicates of gate regions and gate electrodes are formed on either side of each channel region. Therefore, both electrodes on either side of channel regions of conventional VJFETs are gate electrodes, controlling the current flow between drain and source, and creating a high gate-drain capacitance (C_{GD}) and gate-source capacitance (C_{GS}). Furthermore, in conventional VJFETs a reverse current (also referred to as source-drain current or 3rd quadrant current) conduction path does not exist, and current flow between drain and source approaches zero during their operation in the off-state. Such feature, namely having a bi-directional current flow or providing a 3rd quadrant current-conduction path with a reduced source-drain voltage (V_{SD}) drop, may be utilized in power converter topologies and applications.

Moreover, while a dual gate cascode structure of a VJFET in series with a low-voltage metal oxide semiconductor field-effect transistor (MOSFET) (herein after referred to as the “cascode structure”) reduces the on-state resistance by driving the VJFET into positive V_{GS} values and provides an improved control of switching characteristics by enabling the gate of the VJFET device to be directly driven; nonetheless, cascode structures utilized in hard switching applications experience excessive 3rd quadrant energy losses due to the 3rd quadrant current (I_{SD}) flowing through the VJFET channel region and the source-drain voltage (V_{SD}) exceeding the absolute value of VJFET's threshold voltage (Vₜₕ).

For these and other reasons, there is a general need to reduce the structural gate-drain capacitance (C_{GD}) and gate-source capacitance (C_{GS}) of VJFET structures with a minimal impact to their on-state operation behavior. Furthermore, having a 3rd quadrant current conduction path with a minimal source-drain voltage (V_{SD}) drop and a specific on-resistance in cascode configuration is desired. A reduced specific on-resistance in cascode configuration provides a better control over switching characteristics of the cascode structure, leading to a reduction in energy losses.

The present disclosure provides improved design structures through incorporation of anti-parallel source-drain diode cells into depletion-mode trench VJFET cells. The integration of an anti-parallel source-drain diode cell into a depletion-mode trench VJFET cell reduces the structural gate-drain capacitance (C_{GD}), gate-source capacitance (C_{GS}), and switching energy losses. Said integration further reduces the saturation current density (Jₛₐₜ) while maintaining the same threshold voltage (Vₜₕ) with minimal impact on the specific on-resistance (R_{ds}A) of trench VJFET cells.

Depletion-mode trench VJFET cells with integrated source-drain diodes maintain an improved switching performance and reduced switching losses. A reduction in saturation current density provides a longer cascode short-circuit withstand time and an improved safe-operating area (SOA). In the event of a 3rd quadrant current surge, the current is uniformly distributed across the active area of the body region, which reduces the probability of a stacking fault growth. Lastly, having a directly accessible gate electrode forms a dual gate cascode configuration, which allows the VJFET's channel to be turned on during the 3rd quadrant operation.

### SUMMARY

Embodiments of the present disclosure provide vertical junction field-effect transistors (VJFETs) monolithically integrated with anti-parallel PN diodes. These structures can be connected in series with a low-voltage metal oxide semiconductor field-effect transistor (MOSFET) to form a dual gate cascode structure.

In one aspect, a semiconductor structure comprising a drain-cathode electrode, a substrate over the drain-cathode electrode, and a body region over the substrate is disclosed wherein the body region comprises a top surface, a first source region extending into the body region from the top surface, a first U-shaped gate region having a portion below the first source region and defining a first gate trench, and a U-shaped anode region having a first portion below the first source region and defining an anode trench. The semiconductor structure further comprises a first source electrode over the first source region and between the first gate trench and the anode trench, a first gate electrode over a portion of a bottom surface of the first gate trench, and an anode electrode over a portion of a bottom of the anode trench, wherein the first source electrode and the anode electrode are electrically coupled, the first gate region forms part of a first vertical junction field-effect transistor (JFET) cell, and the anode region forms part of a vertical diode cell, which is coupled anti-parallel with the first vertical JFET cell. The substrate and the body region may comprise silicon carbide. The first gate region and the anode region may be doped with a p-type dopant and a remaining portion of the body region and the substrate may be doped with an n-type dopant.

In an embodiment, the first source electrode and the anode electrode may integrally form part of a continuous electrode structure that covers at least a portion of the first source region, a portion of a first side wall of the anode trench, and a portion of the bottom of the anode trench. In an alternative embodiment, the first source electrode and the anode electrode integrally form part of a continuous electrode structure that covers at least a portion of the first source region, a first side wall of the anode trench, and the bottom of the anode trench.

The body region further comprises a first channel region below the first source region and between the first gate region and the anode region. The semiconductor structure may further comprise a secondary channel region doped with an n-type dopant and extending vertically into a central region within the first channel region wherein the maximum doping concentration of the secondary channel region is at least 50% higher than minimum doping concentration of the first channel region. In another embodiment, the semiconductor structure comprises a pair of secondary channel regions doped with n-type dopants and extending on the vertical inner walls within the first channel region wherein the maximum doping concentration of the secondary channel regions is at least 50% higher than minimum doping concentration of the first channel region.

The semiconductor structure may further comprise a second source region extending into the body region from the top surface, a second U-shaped gate region having a portion below the second source region and defining a second gate trench wherein the anode region has a second portion below the second source region such that the anode trench is between the first gate trench and the second gate trench, a second source electrode over the second source region and between the second gate trench and the anode trench, and a second gate electrode over a portion of a bottom surface of the second gate trench, wherein the first source electrode, the second source electrode, and the anode electrode are electrically coupled, wherein the second gate region forms part of a second vertical JFET cell located on the opposite side of the first vertical JFET cell from the vertical diode cell, and the vertical diode cell is coupled anti-parallel with the first vertical JFET cell and the second vertical JFET cell. The substrate and the body region may comprise silicon carbide. The first gate region, the second gate region, and the anode region may be doped with a p-type dopant and remaining portions of the body region and the substrate are doped with an n-type dopant.

In an embodiment, the first source electrode, the second source electrode, and the anode electrode integrally form part of a continuous electrode structure that covers at least a portion of the first source region, at least a portion of the second source region, a portion of a first side wall of the anode trench, a portion of the bottom of the anode trench, and a portion of second side wall of the anode trench. Alternatively, the first source electrode, the second source electrode, and the anode electrode integrally form part of a continuous electrode structure that covers at least a portion of the first source region, a portion of the second source region, a first side wall of the anode trench, the bottom of the anode trench, and a second side wall of the anode trench.

The semiconductor structure further comprises a dielectric material filling portions of the first gate trench and the second gate trench to isolate the first gate electrode from the first source electrode and to isolate the second gate electrode from the second source electrode. The semiconductor structure further comprises a first metal overlay over the first source electrode, the second source electrode, the first gate trench, the anode trench, and the second gate trench.

The body region may further comprise a drift layer above the substrate and doped with an n-type dopant. The body region may further comprise a current spreading layer above the drift layer and below the first gate region and the second gate region and doped with an n-type dopant.

In an embodiment, the body region comprises a first channel region below the first source region and between the first gate region and the anode region and a second channel region below the second source region between the second gate region and the anode region. The semiconductor structure may comprise a first secondary channel region doped with an n-type dopant and extending vertically into a central region of the first channel region and a second secondary channel region doped with an n-type dopant and extending vertically into a central region of the second channel region wherein the maximum doping concentration of the secondary channel region is at least 50% higher than minimum doping concentration of the first channel region. Alternatively, the semiconductor structure may comprise a first pair of secondary channel regions doped with an n-type dopant and extending on the vertical inner walls within the first channel region and a second pair of secondary channel regions doped with an n-type dopant and extending on the vertical inner walls within the second channel region wherein the maximum doping concentrations of the first secondary channel regions and the second secondary channel regions are at least 50% higher than minimum doping concentration of the first channel region.

In a second aspect of the present disclosure, a device structure is disclosed. The device structure comprises a semiconductor structure comprising a drain-cathode electrode, a substrate over the drain-cathode electrode, and a body region over the substrate. The body region comprises a top surface, a first source region extending into the body region from the top surface, a first U-shaped gate region having a portion below the first source region and defining a first gate trench, and a U-shaped anode region having a first portion below the first source region and defining an anode trench. The semiconductor structure further comprises a first source electrode over the first source region and between the first gate trench and the anode trench, a first gate electrode over a portion of a bottom surface of the first gate trench, an anode electrode over a portion of a bottom of the anode trench, wherein the first source electrode and the anode electrode are electrically coupled, the first gate region forms part of a first vertical junction field-effect transistor (JFET) cell, and the anode region forms part of a vertical diode cell, which is coupled anti-parallel with the first vertical JFET cell. The device structure further comprises a metal oxide semiconductor field-effect transistor (MOSFET) comprising a gate electrode, a source electrode, and a drain electrode, wherein the drain electrode of the MOSFET is coupled in series to the first source electrode of the first vertical JFET cell coupled anti-parallel with the vertical diode cell, forming a dual-gate cascode FET device.

In an embodiment, the semiconductor structure further comprises a second source region extending into the body region from the top surface, a second U-shaped gate region having a portion below the second source region and defining a second gate trench, wherein the anode region has a second portion below the second source region such that the anode trench is between the first gate trench and the second gate trench, a second source electrode over the second source region and between the second gate trench and the anode trench, a second gate electrode over a portion of a bottom surface of the second gate trench, wherein the first source electrode, the second source electrode, and the anode electrode are electrically coupled, and wherein the second gate region forms part of a second vertical JFET cell located on the opposite side of the first vertical JFET cell from the vertical diode cell, and the vertical diode cell is coupled anti-parallel with the first vertical JFET cell and the second vertical JFET cell.

In a third aspect of the present disclosure a method of fabricating a semiconductor structure is disclosed. The method comprises providing a drain-cathode electrode, providing a substrate over the drain-cathode electrode, providing a body region over the substrate wherein the body region comprises a top surface, a first source region extending into the body region from the top surface, a first U-shaped gate region having a portion below the first source region and defining a first gate trench, and a U-shaped anode region having a first portion below the first source region and defining an anode trench. The method further comprises providing a first source electrode over the first source region and between the first gate trench and the anode trench, providing a first gate electrode over a portion of a bottom surface of the first gate trench, providing an anode electrode over a portion of a bottom of the anode trench, and electrically coupling the first source electrode and the anode electrode such that the first gate region forms part of a first vertical junction field-effect transistor (JFET) cell, and the anode region forms part of a vertical diode cell, which is coupled anti-parallel with the first vertical JFET cell.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIGS. 1A and 1B illustrate cross-sectional views of exemplary embodiments of depletion-mode trench gate vertical junction field-effect transistors (VJFETs) with integrated source-drain anti-parallel diodes.

FIG. 2 shows an exemplary dual-gate cascode FET configuration comprising a plurality of alternating trench VJFET cells and anti-parallel source-drain diode cells connected in series with a metal oxide semiconductor field-effect transistor (MOSFET).

FIG. 3 illustrates a perspective view of a trench VJFET with an integrated anti-parallel source-drain diode forming a single unit cell having a gate-drain capacitance C_{GD} and a gate-source capacitance C_{GS}.

FIG. 4 depicts the electron flow lines through a single unit cell embodiment as illustrated schematically with flow lines.

FIGS. 5A-5C depict exemplary embodiments of single unit cells having one or more secondary vertical channel regions.

FIG. 6 is a perspective top view layout of a single unit cell embodiment as shown in FIG. 3.

FIG. 7 is a perspective top view layout of altering depletion-mode trench gate VJFETs with integrated source-drain anti-parallel diodes.

FIG. 8 shows a modeled curve chart of saturation current density (Jₛₐₜ) versus the specific on-resistance (R_{DS}A) for a single unit cell embodiment as shown in FIG. 3.

FIG. 9 shows a modeled curve chart of saturation current density (Jₛₐₜ) versus the threshold voltage (Vₜₕ) for a single unit cell embodiment as shown in FIG. 3.

FIG. 10 shows a modeled curve chart of gate-source breakdown voltage (BV_{GS}) versus the threshold voltage (Vₜₕ) for a single unit cell embodiment as shown in FIG. 3.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It should be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It should also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

It should be understood that, although the terms “upper,” “lower,” “bottom,” “intermediate,” “middle,” “top,” and the like may be used herein to describe various elements, these elements should not be limited by these terms. These terms are only used to distinguish one element from another. For example, a first element could be termed an “upper” element and, similarly, a second element could be termed an “upper” element depending on the relative orientations of these elements, without departing from the scope of the present disclosure.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having meanings that are consistent with their meanings in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

Conventional trench vertical junction field-effect transistor (VJFET) structures are created by etching trenches into a topside of a semiconductor material wherein gate regions are formed on both sides and bottoms of the trenches such that mirror-image replicates of gate regions and gate electrodes are formed on either side of each channel region. Therefore, both electrodes on either side of channel regions of conventional VJFETs are gate electrodes, controlling the current flow between drain and source, and creating a high gate-drain capacitance (C_{GD}) and gate-source capacitance (C_{GS}). Furthermore, in conventional VJFETs a reverse current (also referred to as source-drain current or 3rd quadrant current) conduction path does not exist, and current flow between drain and source approaches zero during their operation in the off-state. Such feature, namely having a bi-directional current flow or providing a 3rd quadrant current-conduction path with a reduced source-drain voltage (V_{SD}) drop, may be utilized in power converter topologies and applications.

Moreover, while a dual gate cascode structure of a VJFET in series with a low-voltage metal oxide semiconductor field-effect transistor (MOSFET) (herein after referred to as the “cascode structure”) reduces the on-state resistance by driving the VJFET into positive V_{GS} values and provides an improved control of switching characteristics by enabling the gate of the VJFET device to be directly driven, nonetheless, cascode structures utilized in hard switching applications experience excessive 3rd quadrant energy losses due to the 3rd quadrant current (I_{SD}) flowing through the VJFET channel region and the source-drain voltage (V_{SD}) exceeding the absolute value of VJFET's threshold voltage (Vₜₕ).

Embodiments of the present disclosure provide VJFETs monolithically integrated with anti-parallel PN diodes. These structures can be applied to a variety of semiconductor devices including but not limited to other types of transistors and diodes and to other e-channel and p-channel JFET structures. A normally-off operation mode can be implemented by connecting the normally-on VJFET with an anti-parallel diode structure to a low-voltage MOSFET in a cascode configuration.

Merely by way of example, the concepts described herein have been applied to integration of these structures in silicon carbide (SiC) or gallium nitride (GaN). Other wide bandgap materials may be used for the integration of various embodiments disclosed herein. Alternatively, silicon (Si) (another primary semiconductor used in power electronic devices) may be used for the integration of various embodiments disclosed herein. SiC material properties make SiC JFETs attractive for high power conversion and high-power density applications. SiC JFETs are also of great interest in power electronic circuits for high-frequency power applications or circuit protection functions due to their superior performance compared with similar devices built on silicon.

It is to be appreciated that certain features of the disclosure which are, for clarity, described herein in the context of separate embodiments may also be provided in combination in a single embodiment. Conversely, various features of the invention that are, for brevity, described in the context of a single embodiment may also be provided separately or in any sub-combination.

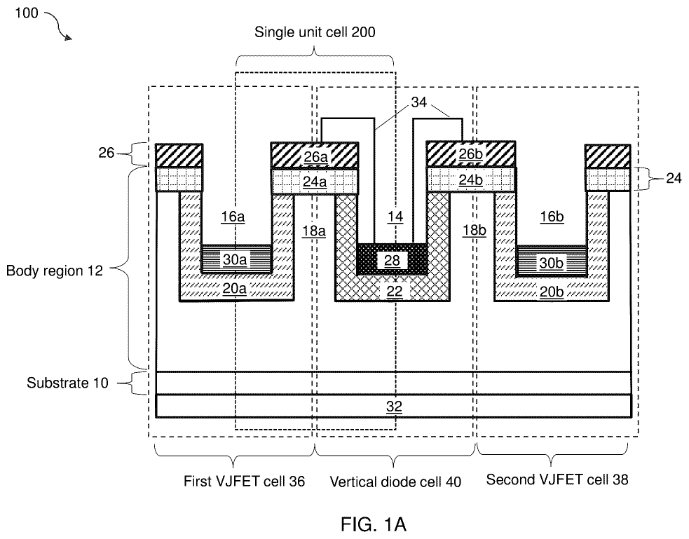

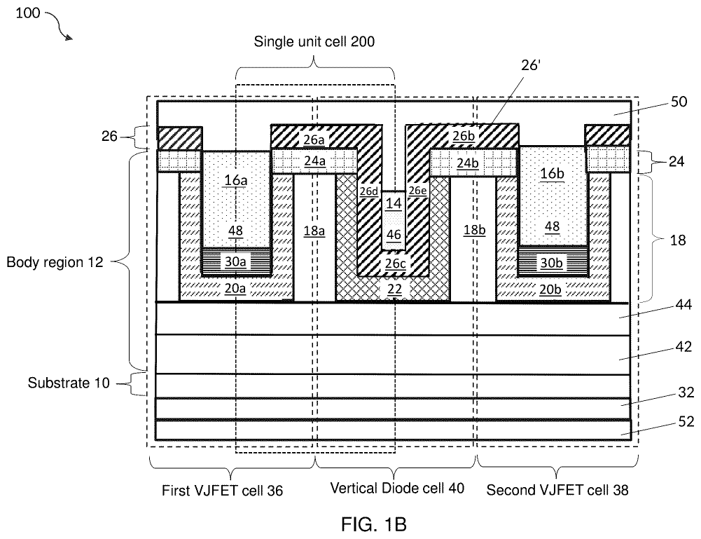

FIGS. 1A and 1B illustrate cross-sectional views of exemplary embodiments of depletion-mode trench gate VJFETs with integrated source-drain anti-parallel diodes. It should be understood that the structures illustrated in FIGS. 1A and 1B are exemplary and are simplified and that the scope of the invention is not limited to these specific examples. Furthermore, the dimensions in the figures of this application are not to scale, and at times the relative dimensions are exaggerated or reduced in size to more clearly show various structural features.

While only three trenches are shown in each figure, it is to be understood that the structures illustrated may be replicated many times in an actual semiconductor device. Also, while due to the higher mobility of electrons compared with that of holes in SiC, the majority carriers in structures illustrated in these figures are electrons. It is further to be understood that the structures illustrated may be replicated with holes as the majority carriers in the case of which polarity signs and the directions of electric field and electric flux density may be reversed.

FIG. 1A illustrates a cross-sectional view of an exemplary embodiment of depletion-mode trench gate vertical JFETs (VJFETs) with integrated source-drain anti-parallel diodes (herein after referred to as “VJFET-diode structure 100”) which are built on a wafer comprising a substrate 10 and a body region 12, both of which are doped with an n-type dopant.

A source region 24 extends into a top surface of the body region 12 using an ion implantation or epitaxial growth process. An anode trench 14, a first gate trench 16a, and a second gate trench 16b are formed by etching trenches into a top surface of the body region 12 such that each trench extends vertically downward into the body region 12 from the top surface thereof. Although FIG. 1A illustrates examples of trenches according to some embodiments of the present invention, it will be understood that the present invention is not limited to such configurations. For example, trenches adjacent to each other as described in the first embodiment may be of different depths or different widths. In various embodiments, adjacent trenches may dispose a different distance apart from one another.

The anode trench 14, the first gate trench 16a, and the second gate trench 16b form a first source region 24a and a second source region 24b as part of the source region 24. The first source region 24a is formed under the top surface of the body region 12 between the first gate trench 16a and the anode trench 14, and the second source region 24b is formed under the top surface of the body region 12 between the second gate trench 16b and the anode trench 14. The source region 24, which includes the first source region 24a and the second source region 24b, is doped with an n+ dopant having a doping concentration ranging from 5e17 cm⁻³ to 1e21 cm⁻³. It should be appreciated that the thickness and doping concentration of the source region 24 may vary according to applications and fabrication processes.

Under the source region 24, bottom and sidewalls surrounding each of the first gate trench 16a, the second gate trench 16b, and the anode trench 14 are doped with a p-type dopant to form a first gate region 20a, a second gate region 20b, and an anode region 22, respectively, such that the first gate region 20a forms a U-shaped region under the source region 24 that defines the first gate trench 16a with a first portion of the U-shaped region under the first source region 24a. Similarly, the anode region 22 forms a U-shaped region under the source region 24 to define the anode trench 14 with a first portion of the U-shaped region under the first source region 24a.

The doping process is through ion implantation using vertical and/or angled implants and may combine multiple implantation energies and tilt and rotation angles and may be performed at high temperature (above room temperature) while the doping type of the dopant used is opposite that of the body region 12. In one embodiment, trench sidewalls may be partially implanted or have a narrower doped region to reduce the structure's specific on-resistance (R_{ds}A). The doping type of the first gate region 20a, the second gate region 20b, and the anode region 22 are opposite those of the source region 24, the body region 12, and the substrate 10. The first gate region 20a, the second gate region 20b, and the anode region 22 may have a doping concentration ranging from 1e17 cm⁻³ to 5e20 cm⁻³.

In practice, ohmic contacts may be used to reduce the contact resistance between the semiconductor and the metal electrodes and to enhance the overall conductance of the VJFET-diode structure 100. Therefore, a first and a second source ohmic contacts (not shown here for simplicity and clarity) may form part of the first source region 24a between the first gate trench 16a and the anode trench 14 and of the second source region 24b between the second gate trench 16b and the anode trench 14. The heavily doped n+ source region 24 forms PN junctions with the first gate region 20a, the second gate region 20b, and the anode region 22, which facilitates gate control in the JFET cell. Similarly, a drain ohmic contact (not shown) may form part of a back surface of the substrate 10, a first and a second gate ohmic contact (not shown) may form part of bottom surfaces of the first gate trench 16a and the second gate trench 16b, and an anode ohmic contact (not shown) may form part of a bottom surface of the anode trench 14.

A first channel region 18a and a second channel region 18b form part of the body region 12. The first channel region 18a extends vertically into the body region 12 from below the first source region 24a and forms laterally in between the first gate region 20a and the anode region 22. The second channel region 18b extends vertically into the body region 12 below the second source region 24b and forms laterally in between the anode region 22 and the second gate region 20b. It should be noted that while only two channel regions are shown in FIG. 1A, the structures illustrated may be replicated many times to form a plurality of channel regions in a semiconductor device designed according to disclosures of the present application.

As shown in FIG. 1A, metal deposits over top surfaces of source regions 24 form source electrodes 26 including a first source electrode 26a covering the top surface of the first source region 24a and between the first gate trench 16a and the anode trench 14 and a second source electrode 26b covering the top surface of the second source region 24b and between the second gate trench 16b and the anode trench 14. Similarly, metal regions over at least a portion of bottom surfaces of the first gate trench 16a and a second gate trench 16b provide a first gate electrode 30a and a second gate electrode 30b. Metal deposits over at least a portion of a bottom surface of the anode trench 14 provide an anode electrode 28, and metal deposits over a backside surface of the substrate 10 provide a drain-cathode electrode 32. Electrical couplings 34 are used to electrically connect each of the first source electrode 26a and the second source electrode 26b to the anode electrode 28 in order to hold the anode electrode 28 at the same electrical potential as the first source electrodes 26a and the second source electrode 26b.

In the simplified cross-sectional view of the embodiment shown in FIG. 1A, the anode electrode 28, the anode region 22, and the drain-cathode electrode 32 form part of a vertical diode cell 40. As part of the same VJFET-diode structure 100, the first source electrode 26a and the first source region 24a along with the drain-cathode electrode 32, the first gate electrode 30a, and the first gate region 20a form part of a first VJFET cell 36. Similarly, the second source electrode 26b and the second source region 24b along with the drain-cathode electrode 32, the second gate electrode 30b, and the second gate region 20b form part of a second VJFET cell 38, which is located on the opposite side of the first VJFET cell 36 from the vertical diode cell 40, and the vertical diode cell 40 is coupled anti-parallel with the first VJFET cell 36 and the second VJFET cell 38.

A single unit cell 200 as shown in the exemplary embodiment of FIG. 1A includes portions of the first VJFET cell 36 and portions of the vertical diode cell 40 adjacent to it. The integration of the source-drain anti-parallel diode into the depletion-mode trench VJFET semiconductor structure allows a 3rd quadrant current conduction while the VJFET is in off-state with a significant reduction of saturation current density (Jₛₐₜ) and maintaining a similar threshold voltage (Vₜₕ) and specific on-resistance (R_{ds}A).

FIG. 1B shows a cross-sectional view of an exemplary embodiment of depletion-mode trench gate VJFET with integrated source-drain anti-parallel diodes (herein after referred to as “VJFET-diode structure 100”). As shown in FIG. 1B, the body region 12 may further comprise an n-type drift layer 42 configured to withstand a desired blocking voltage. The drift layer 42 may form above the substrate 10 and have a doping level in the range of 2e14 cm⁻³ to 5e16 cm⁻³. The doping level of the body region 12 may be in the ranges of 2e14 cm⁻³ to 1e17 cm⁻³, and the doping level of the substrate 10 may be in the range of 2e17 cm⁻³ to 1e19 cm⁻³.

The body region 12 comprises channel regions 18 including the first channel region 18a and the second channel region 18b. The first channel region 18a forms below the first source region 24a and between the first gate region 20a and the anode region 22. The second channel region 18b forms below the second source region 24b and between the second gate region 20b and the anode region 22. The doping level of the channel regions 18, including the first channel region 18a and the second channel region 18b, may be at least two times lower than the lowest doping concentration in the rest of the body region 12 and in the range of 1e14 cm⁻³ to 2e16 cm⁻³.

The body region 12 may also comprise an n-type current spreading layer 44, which may have a doping level in the range of 1e16 cm⁻³ to 1e17 cm⁻³. The current spreading layer 44 may be continuous or segmented and form above the drift layer 42 with its upper boundary positioned below the first gate region 20a and the second gate region 20b. The current spreading layer 44 may further comprise a plurality of other layers of different doping levels formed epitaxially and/or by ion implantation.

Optionally, a heavily doped N-type buffer layer (not shown here) may form over a top surface of the substrate 10 by means of epitaxial growth. It is further noted that while the body region 12, the substrate 10, the first channel region 18a, and the second channel region 18b, buffer, the current spreading layer 44, and source regions 24 including the first source region 24a and the second source region 24b are depicted to have had been doped with an n-type dopant, and while a gate region 20 and the anode region 22 are shown with a p-type dopant, in practice, the doping types can be switched among these same structures.

In an embodiment, the first source electrode 26a and the anode electrode 28 integrally form part of a continuous electrode structure 26′ that covers over at least a portion of the first source region 24a to provide the first source electrode 26a, a portion of a first side wall of the anode region 22 adjacent to the first source electrode 26a to form a first sidewall electrode 26d, and a portion of the bottom of anode trench 14 to form a bottom surface (anode) electrode 26c. According to another embodiment, the first source electrode 26a and the anode electrode 28 integrally form part of the continuous electrode structure 26′ that covers over at least a portion of the first source region 24a to provide the first source electrode 26a, the first side wall of the anode region 22 adjacent to the first source electrode 26a to form the first sidewall electrode 26d, and the bottom of anode trench 14 to form the bottom surface (anode) electrode 26c.

The first source electrode 26a, the second source electrode 26b, and the anode electrode 28 may integrally form part of a continuous electrode structure 26′ that covers at least a portion of the first source region 24a to provide the first source electrode 26a, a portion of the first side wall of the anode region 22 adjacent to the first source electrode 26a to form the first sidewall electrode 26d, a portion of the bottom of anode trench 14 to form the bottom surface (anode) electrode 26c, a portion of the second side wall of the anode region 22 adjacent to the second source electrode 26b to form the second sidewall electrode 26e, and at least a portion of the second source region 24b to provide the second source electrode 26b.

In yet another embodiment, the first source electrode 26a, the second source electrode 26b, and the anode electrode 28 integrally form part of a continuous electrode structure 26′ that covers at least a portion of the first source region 24a to provide the first source electrode 26a, the first side wall of the anode region 22 adjacent to the first source electrode 26a to form the first sidewall electrode 26d, the bottom of anode trench 14 to form the bottom surface (anode) electrode 26c, the second side wall of the anode region 22 adjacent to the second source electrode 26b to form a second sidewall electrode 26e, and at least a portion of the second source region 24b to provide the second source electrode 26b.

A mostly self-aligned silicidation (salicidation) process may be used to form a separated first and second gate electrodes 30a and 30b, a continuous electrode structure 26′ that couples the first source electrode 26a of the first VJFET cell 36 with the bottom surface (anode) electrode 26c of the vertical diode cell 40 and the second source electrode 26b of the second VJFET cell 38. The source metal for silicidation process may include, but not limited to, nickel and titanium. A drain-cathode electrode 32 may be formed by a combination of metal deposition and laser irradiation.

The structure of FIG. 1B depicts an embodiment wherein the first gate trench 16a and the second gate trench 16b are filled with a gate trench dielectric material 48. The gate trench dielectric material 48 is used to ensure the electrical isolation of the first source electrode 26a and the first gate electrode 30a in the first VJFET cell 36 and the electrical isolation of the second source electrode 26b and second gate electrode 30b in the second VJFET cell 38.

In an embodiment, the anode trench 14 is filled with an anode trench dielectric material 46. A portion of the anode trench dielectric material 46 may be removed in order to maximize the exposure of the continuous electrode structure 26′. The method and process of fabrication used may control the amount of anode trench dielectric material 46 that is removed from the anode trench 14. In another embodiment, the anode trench dielectric material 46 is entirely removed from the anode trench 14, allowing the trench to be fully filled with a first metal overlay 50. The first metal overlay 50 is deposited over the topside of the semiconductor structure to form a thick metal overlay which improves the conductivity of source-anode electrical connection.

The first metal overlay 50 covers source electrodes 26 and the exposed portions of the continuous electrode structure 26′ while filling the anode trench 14 to replace the removed portions of the anode trench dielectric material 46 to form contact with portions of the first sidewall electrode 26d and the second sidewall electrode 26e. The first metal overlay 50 may combine different metal sub-layers (not shown) including but not limited to metal layers composed of aluminum (Al), aluminum-copper (Al—Cu), copper (Cu), titanium (Ti), tungsten-titanium (TiW), tungsten (W), titanium nitride (TiN), palladium (Pd), and gold (Au).

In an embodiment, a final topside passivation layer (not shown) comprising a combination of chemical vapor deposition (CVD) dielectrics and polyimide may be deposited over the top surface of the first metal overlay 50 at a periphery of a semiconductor die used to fabricate VJFET-diode structure 100.

A second metal overlay 52 is deposited at least partially over the backside of the drain-cathode electrode 32. Multiple metallization layers (not shown) including one or more of Ni, Ti, TiW, TIN, W, Pd, Au, and silver (Ag) may comprise the second metal overlay 52.

Basal plane defect (BPD) and stacking fault screening has to be implemented on starting an epitaxial wafer and at device level in the same manner as it is implemented in silicon carbide MOSFETs with built-in source-drain diode.

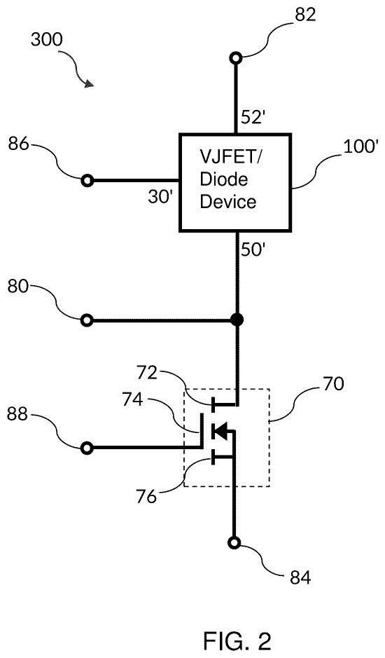

FIG. 2 shows an exemplary dual-gate cascode FET configuration 300 comprising a plurality of alternating trench VJFET cells and anti-parallel source-drain diode cells (herein after referred to as “VJFET/diode structure 100′”) connected in series with a MOSFET 70. The VJFET/diode structure 100′ comprises a unified drain electrode 52′, a unified gate electrode 30′, and a unified source electrode 50′. The MOSFET 70 may be a low-voltage transistor having a MOSFET drain electrode 72, a MOSFET gate electrode 74, and a MOSFET source electrode 76. The MOSFET drain electrode 72 is coupled to the unified source electrode 50′ of the VJFET/diode structure 100′ forming an intermediary electrode 80 for the dual-gate cascode FET configuration 300 having a drain electrode 82, a source electrode 84, a first gate electrode 86, and a second gate electrode 88. The first gate electrode 86 is the unified gate electrode 30′ of the VJFET/diode structure 100′, and the second gate electrode 88 is the MOSFET gate electrode 74. The drain electrode 82 is the unified drain electrode 52′ of the VJFET/diode structure 100′, and the source electrode 84 is the MOSFET source electrode 76. The dual-gate cascode FET configuration 300 reduces the on-resistance of VJFET/diode structure 100′. The unified gate electrode 30′ of the VJFET/diode structure 100′ can be driven into positive V_{GS} values utilizing the first gate electrode 86, which further improves controlling of switching behavior of the VJFET/diode structure 100′. The second gate electrode 88, which is the MOSFET gate electrode 74, provides general on/off control for the dual-gate cascode FET configuration 300.

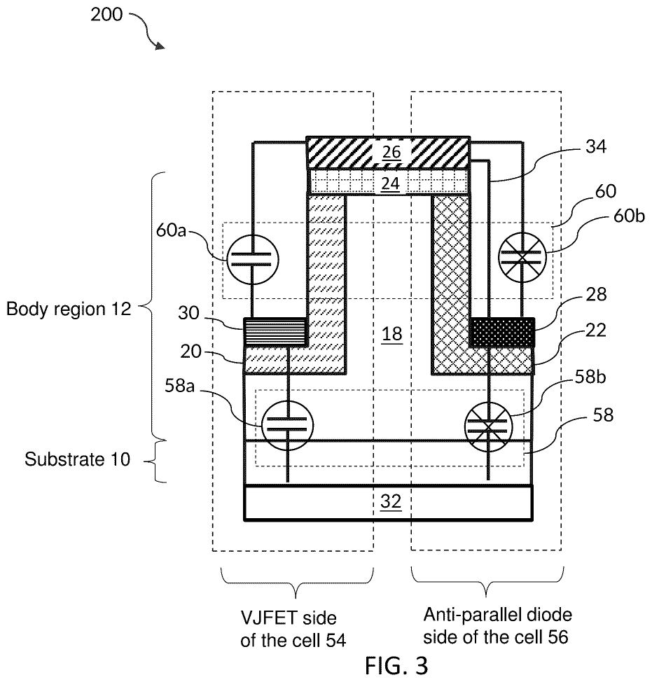

FIG. 3 illustrates a perspective view of a trench VJFET with an integrated anti-parallel source-drain diode forming a single unit cell 200 having a gate-drain capacitance C_{GD} 58 and a gate-source capacitance C_{GS} 60. The single unit cell 200 comprises a VJFET side of the cell 54 and an anti-parallel diode side of the cell 56. The VJFET side of the cell 54 comprises a gate region 20, a source region 24, a source electrode 26, a gate electrode 30, and a drain-cathode electrode 32. The anti-parallel diode side of the cell 56 comprises an anode region 22, an anode electrode 28, and the drain-cathode electrode 32. The source electrode 26 and the anode electrode 28 are electrically connected using an electrical coupling 34. A channel region 18 forms under the source region 24 and extends vertically into the body region 12 and laterally in between the gate region 20 and the anode region 22.

The integration of an anti-parallel source-drain diode within a trench VJFET structure to form the single unit cell 200 reduces the gate-drain capacitance C_{GD} 58 by approximately 50% to a first gate-drain capacitance C_{GD} 58a and by eliminating a second gate-drain capacitance C_{GD} 58b. Similarly, the integration of an anti-parallel source-drain diode within a trench VJFET structure to form the single unit cell 200 reduces the gate-source capacitance C_{GS} 60 by approximately 50% to a first gate-source capacitance C_{GS} 60a and by eliminating a second gate-source capacitance C_{GS} 60b.

Replacing a second gate electrode of the conventional VJFET (not shown) with the anode electrode 28 and electrically connecting the source electrode 26 to the anode electrode 28 forms an anti-parallel source-drain PN diode that eliminates associated parasitic capacitances with minimal impact on the on-resistance of the single unit cell 200. Cancelled portions of the parasitic gate-drain capacitance C_{GD} 58 and the gate-source capacitance C_{GS} 60 improve the switching behavior of the single unit cell 200 with minimal impact on the on-state behavior of the device. Persons skilled in the art will appreciate that the aforementioned positive effect becomes more pronounced when multiple single unit cells 200 of a vertical trench JFET with integrated source-drain anti-parallel diodes are connected alternating and in parallel as shown in FIGS. 1A and 1B.

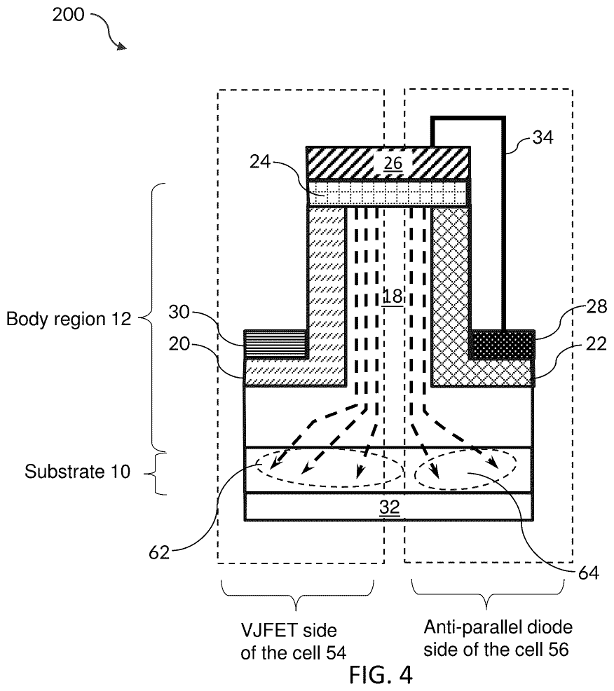

FIG. 4 depicts the electron flow lines (forward current flow is in the opposite direction) through a single unit cell 200 embodiment as illustrated schematically with electron flow lines. As shown in FIG. 4, in the 1^{st} quadrant of the conduction mode, forward current flow occurs through both the VJFET side of the cell 54 and the anti-parallel diode side of the cell 56. The forward current through the VJFET side of the cell 54 as illustrated schematically with VJFET current flow lines 62 and the forward current through the diode side of the cell 56 as illustrated schematically with diode current flow lines 64 illustrate the minimal impact of integrating a source-drain anti-parallel diode within the device structure as forward current continues to spread efficiently through the entire structure.

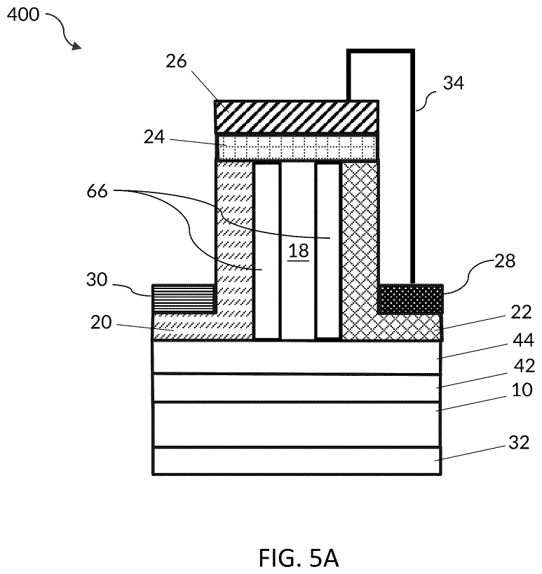

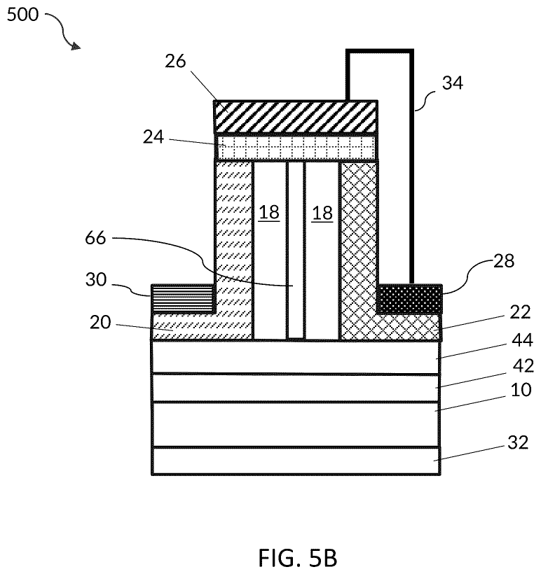

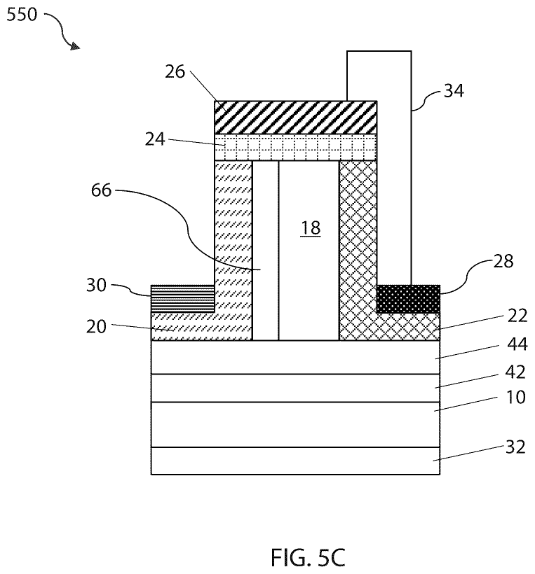

FIGS. 5A-5C depict exemplary embodiments of a first single unit cell 400, a second single unit cell 500, and a third single unit cell 550, respectively, each having one or more secondary vertical channel regions 66. The one or more secondary vertical channel regions 66 as shown in FIGS. 5A and 5C may be formed either by angled ion implantation or by vertical ion implantation or a combination of both.

The doping levels of the channel region 18, which may further comprise one or more secondary vertical channel regions 66, affects the operation of the anti-parallel source-drain diode within a trench VJFET to form the single unit cell 200. The threshold voltage (Vₜₕ) can be optimized through adjusting the doping level of the channel region 18 to a value that is much lower than that of the rest of the body region 12 and the substrate 10. For example, the doping level of the channel region 18 may be at least two times lower than the lowest doping concentration in the rest of the body region 12 and in the range of 1e14 cm⁻³ to 2e16 cm⁻³. Furthermore, the maximum doping concentration of the one or more secondary vertical channel regions 66 as shown in FIGS. 5A and 5B may be at least 50% higher than the minimum concentration in the channel region 18.

As illustrated in FIG. 5A, the channel region 18 may further comprise one or more secondary vertical channel regions 66, wherein the one or more secondary vertical channel regions 66 run alongside the sidewalls of the channel region 18. In one embodiment, the one or more secondary vertical channel regions 66 may have a maximum doping level that is at least 50% higher than minimum doping level in the channel region 18.

FIG. 5B illustrates an exemplary embodiment of a secondary vertical channel region 66, wherein the secondary vertical channel region 66 runs alongside the center of the channel region 18. The secondary vertical channel region 66 as shown in FIG. 5B has a maximum doping level that is at least 50% higher than a minimum doping level of the channel region 18.

FIG. 5C illustrates an exemplary embodiment of a secondary vertical region 66, wherein the secondary vertical channel region 66 runs along the sidewall of the channel region 18 that is one the side of the gate electrode 30 but there is no secondary vertical region 66 on the sidewall on the side of the anode 28. By placing the secondary vertical region 66 only on the sidewall adjacent to the gate electrode 30, the process of manufacturing the third single unit cell 550 is simplified since secondary vertical channel region 66 only has to be implemented on one sidewall. Furthermore, in some embodiments, the benefit of having another secondary vertical channel region 66 along the side of the body like the first single unit cell 400 may be limited since the gate electrode 30 will primarily affect the operation of the adjacent secondary vertical channel in both forward conduction and off-state blocking.

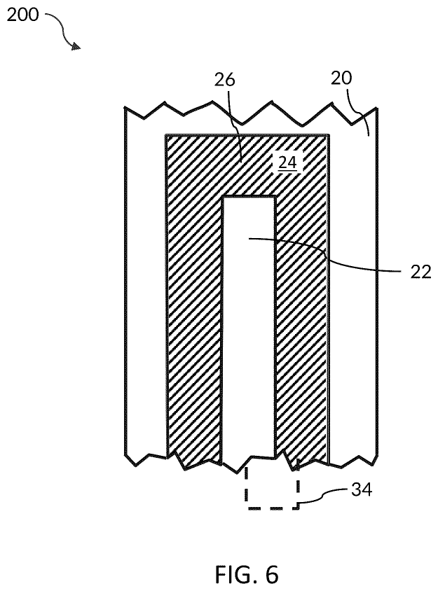

FIG. 6 is a perspective top view layout of a single unit cell embodiment 200 as shown in FIG. 3. In order to increase the current rating of the device, multiple single unit cells may be connected in parallel with the alternating gate regions 20 and the anode regions 22. As shown in the top view layout of the single unit cell 200 embodiment, the anode region 22 is surrounded by the source region 24 mesa and the source region mesa 24 is itself surrounded by the gate region 20. The electrical coupling 34 is used to electrically connect the anode electrode (not shown) to the source electrode 26 that is disposed over a top surface of the source region 24.

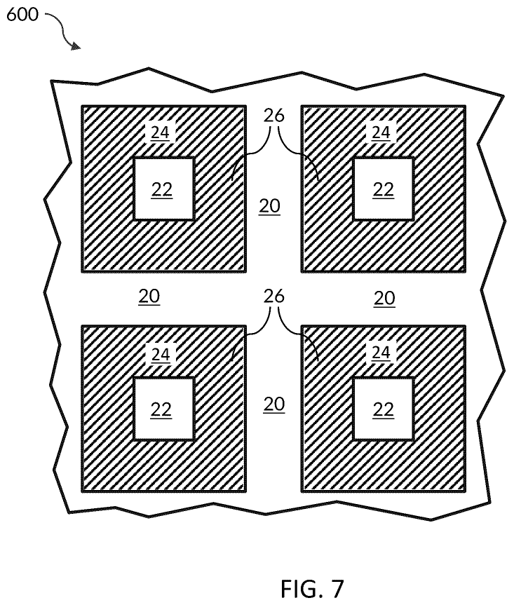

FIG. 7 is a perspective top view layout of altering depletion-mode trench gate vertical JFETs with an integrated source-drain anti-parallel diodes 600. In an exemplary embodiment, the cell layout comprises the anode region 22 of multiple diode cells that are fully surrounded by source mesas (not shown) having the source electrode 26 over their top surfaces. The gate regions 20 form a grid pattern between the isolated anode regions 22 surrounded by source region 24 mesas covered with the source electrodes 26.

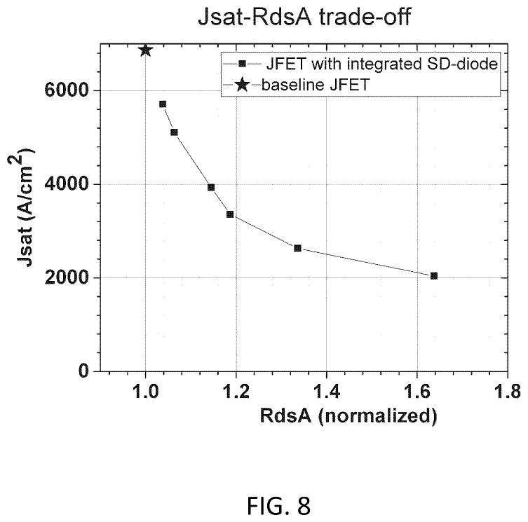

FIG. 8 shows a modeled curve chart of saturation current density (Jₛₐₜ) versus the specific on-resistance (R_{DS}A) for the single unit cell 200 embodiment of a trench VJFET with an integrated anti-parallel source-drain as shown in FIG. 3 under exemplary operation values of V_{GS}=0 V and V_{DS}=800 V. The curve chart of FIG. 8 shows that compared with the baseline obtained from a conventional trench VJFET design with no integrated source-drain diode, the integration of a source-drain anti-parallel diode reduces Jₛₐₜ values by approximately 50% with minimal impact (approximately 20% increase) on R_{DS}A. The substantial reduction of Jₛₐₜ may significantly improve the short-circuit withstand time, allowing for more time for protective circuitry to shut-off the gate of the VJFET in case of a short-circuit event.

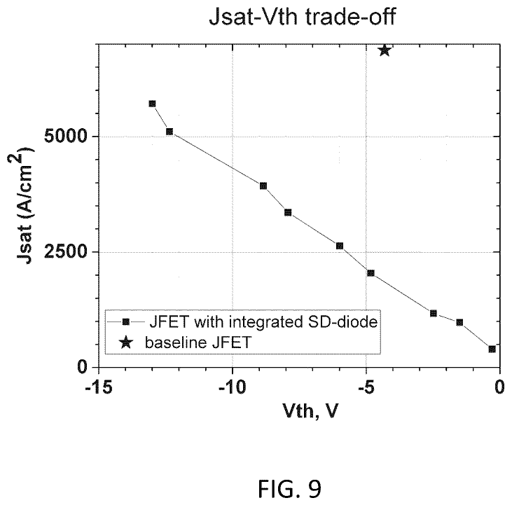

FIG. 9 shows a modeled curve chart of saturation current density (Jₛₐₜ) versus the threshold voltage (Vₜₕ) for the single unit cell 200 embodiment of a trench VJFET with an integrated anti-parallel source-drain as shown in FIG. 3 under exemplary operation values of V_{GS}=0 V and V_{DS}=800 V. The curve chart of FIG. 9 further illustrates that compared with the baseline obtained from a conventional trench VJFET design with no integrated source-drain diode, the integration of a source-drain anti-parallel diode into a trench VJFET structure allows for a significant reduction of saturation current density (Jₛₐₜ) with minimal impact on the threshold voltage (Vₜₕ).

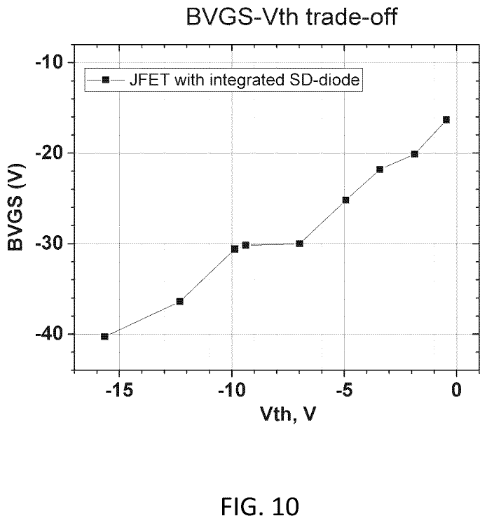

FIG. 10 shows a modeled curve chart of gate-source breakdown voltage (BV_{GS}) versus the threshold voltage (Vₜₕ) for the single unit cell 200 embodiment of a trench VJFET with an integrated anti-parallel source-drain as shown in FIG. 3. To turn off a normally-on VJFET device, a V_{GS} that is lower (more negative in value) than VJFET's threshold voltage (Vₜₕ) must be applied. However, such low value of V_{GS} may deplete the channel region 18 and result in a punch-through breakdown between the gate region 20 and the anode region 22. As shown in the modeled curve chart, embodiments of the present disclosure provide improved design structures with significant safety margin values (in the range of 20V to 25V) between Vₜₕ and their corresponding BV_{GS}, resulting in a feasible structure for practical gate drive conditions.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A semiconductor structure comprising:
a drain-cathode electrode;
a substrate over the drain-cathode electrode;
a body region over the substrate comprising:
a top surface;
a first source region extending into the body region from the top surface;
a first U-shaped gate region having a portion below the first source region and defining a first gate trench; and
a U-shaped anode region having a first portion below the first source region and defining an anode trench;
a first source electrode over the first source region and between the first gate trench and the anode trench;
a first gate electrode over a portion of a bottom surface of the first gate trench;
an anode electrode over a portion of a bottom of the anode trench; and
wherein the first source electrode and the anode electrode are electrically coupled, the first gate region forms part of a first vertical junction field-effect transistor (JFET) cell, and the anode region forms part of a vertical diode cell, which is coupled anti-parallel with the first vertical JFET cell.

2. The semiconductor structure of claim 1 wherein the substrate and the body region comprise silicon carbide.

3. The semiconductor structure of claim 1 wherein the first gate region and the anode region are doped with a p-type dopant and a remaining portion of the body region and the substrate are doped with an n-type dopant.

4. The semiconductor structure of claim 1 wherein the first source electrode and the anode electrode integrally form part of a continuous electrode structure that covers at least a portion of the first source region, a portion of a first side wall of the anode trench, and a portion of the bottom of the anode trench.

5. The semiconductor structure of claim 1 wherein the first source electrode and the anode electrode integrally form part of a continuous electrode structure that covers at least a portion of the first source region, a first side wall of the anode trench, and the bottom of the anode trench.

6. The semiconductor structure of claim 1 wherein the body region further comprises a first channel region below the first source region and between the first gate region and the anode region.

7. The semiconductor structure of claim 6 further comprising a secondary channel region doped with an n-type dopant and extending vertically into a central region within the first channel region.

8. The semiconductor structure of claim 7 wherein a maximum doping concentration of the secondary channel region is at least 50% higher than a minimum doping concentration of the first channel region.

9. The semiconductor structure of claim 6 further comprising a pair of secondary channel regions doped with n-type dopants and extending on vertical inner walls within the first channel region.

10. The semiconductor structure of claim 9 wherein a maximum doping concentration of the secondary channel regions is at least 50% higher than a minimum doping concentration of the first channel region.

11. The semiconductor structure of claim 1 further comprising:
a second source region extending into the body region from the top surface of the body region;
a second U-shaped gate region having a portion below the second source region and defining a second gate trench, wherein the anode region has a second portion below the second source region such that the anode trench is between the first gate trench and the second gate trench;
a second source electrode over the second source region and between the second gate trench and the anode trench; and
a second gate electrode over a portion of a bottom surface of the second gate trench, wherein the first source electrode, the second source electrode, and the anode electrode are electrically coupled; and
wherein the second gate region forms part of a second vertical JFET cell located on the opposite side of the first vertical JFET cell from the vertical diode cell, and the vertical diode cell is coupled anti-parallel with the first vertical JFET cell and the second vertical JFET cell.

12. The semiconductor structure of claim 11 wherein the substrate and the body region comprise silicon carbide.

13. The semiconductor structure of claim 11 wherein the first gate region, the second gate region, and the anode region are doped with a p-type dopant and remaining portions of the body region and the substrate are doped with an n-type dopant.

14. The semiconductor structure of claim 11 wherein the first source electrode, the second source electrode, and the anode electrode integrally form part of a continuous electrode structure that covers at least a portion of the first source region, at least a portion of the second source region, a portion of a first side wall of the anode trench, a portion of the bottom of the anode trench, and a portion of a second side wall of the anode trench.

15. The semiconductor structure of claim 11 wherein the first source electrode, the second source electrode, and the anode electrode integrally form part of a continuous electrode structure that covers at least a portion of the first source region, a portion of the second source region, a first side wall of the anode trench, the bottom of the anode trench, and a second side wall of the anode trench.

16. The semiconductor structure of claim 15 further comprising a dielectric material filling portions of the first gate trench and the second gate trench to isolate the first gate electrode from the first source electrode and to isolate the second gate electrode from the second source electrode.

17. The semiconductor structure of claim 16 further comprising a first metal overlay over the first source electrode, the second source electrode, the first gate trench, the anode trench, and the second gate trench.

18. The semiconductor structure of claim 11 wherein the body region further comprises a drift layer above the substrate and doped with an n-type dopant.

19. The semiconductor structure of claim 18 wherein the body region further comprises a current spreading layer above the drift layer and below the first gate region and the second gate region and doped with an n-type dopant.

20. The semiconductor structure of claim 11 wherein the body region further comprises a first channel region below the first source region and between the first gate region and the anode region and a second channel region below the second source region between the second gate region and the anode region.

21. The semiconductor structure of claim 20 further comprising a first secondary channel region doped with an n-type dopant and extending vertically into a central region of the first channel region and a second secondary channel region doped with an n-type dopant and extending vertically into a central region of the second channel region.

22. The semiconductor structure of claim 21 wherein a maximum doping concentration of the secondary channel region is at least 50% higher than a minimum doping concentration of the first channel region.

23. The semiconductor structure of claim 20 further comprising a first pair of secondary channel regions doped with an n-type dopant and extending on vertical inner walls within the first channel region and a second pair of secondary channel regions doped with an n-type dopant and extending on vertical inner walls within the second channel region.

24. The semiconductor structure of claim 23 wherein maximum doping concentrations of the first pair of secondary channel regions and the second pair of secondary channel regions are at least 50% higher than a minimum doping concentration of the first channel region.

25. A device structure comprising:
a semiconductor structure comprising:
a drain-cathode electrode;
a substrate over the drain-cathode electrode;
a body region over the substrate comprising:
a first source region extending into the body region from a top surface of the body region;
a first U-shaped gate region having a portion below the first source region and defining a first gate trench; and
a U-shaped anode region having a first portion below the first source region and defining an anode trench;
a first source electrode over the first source region and between the first gate trench and the anode trench;
a first gate electrode over a portion of a bottom surface of the first gate trench;
an anode electrode over a portion of a bottom of the anode trench; and
wherein the first source electrode and the anode electrode are electrically coupled, the first gate region forms part of a first vertical junction field-effect transistor (JFET) cell, and the anode region forms part of a vertical diode cell, which is coupled anti-parallel with the first vertical JFET cell;
a metal oxide semiconductor field-effect transistor (MOSFET) comprising a gate electrode, a source electrode, and a drain electrode; and
wherein the drain electrode of the MOSFET is coupled in series to the first source electrode of the first vertical JFET cell coupled anti-parallel with the vertical diode cell, forming a dual-gate cascode FET device.

26. The device structure of claim 25 wherein the semiconductor structure further comprises:
a second source region extending into the body region from the top surface of the body region;
a second U-shaped gate region having a portion below the second source region and defining a second gate trench, wherein the anode region has a second portion below the second source region such that the anode trench is between the first gate trench and the second gate trench;
a second source electrode over the second source region and between the second gate trench and the anode trench;
a second gate electrode over a portion of a bottom surface of the second gate trench, wherein the first source electrode, the second source electrode, and the anode electrode are electrically coupled; and
wherein the second gate region forms part of a second vertical JFET cell located on the opposite side of the first vertical JFET cell from the vertical diode cell, and the vertical diode cell is coupled anti-parallel with the first vertical JFET cell and the second vertical JFET cell.

27. A method of fabricating a semiconductor structure comprising:
providing a drain-cathode electrode;
providing a substrate over the drain-cathode electrode;
providing a body region over the substrate comprising:
a first source region extending into the body region from a top surface of the body region;
a first U-shaped gate region having a portion below the first source region and defining a first gate trench; and
a U-shaped anode region having a first portion below the first source region and defining an anode trench;
providing a first source electrode over the first source region and between the first gate trench and the anode trench;
providing a first gate electrode over a portion of a bottom surface of the first gate trench;
providing an anode electrode over a portion of a bottom of the anode trench; and
electrically coupling the first source electrode and the anode electrode such that the first gate region forms part of a first vertical junction field-effect transistor (JFET) cell, and the anode region forms part of a vertical diode cell, which is coupled anti-parallel with the first vertical JFET cell.
